(19) United States
(12) Patent Application Publication
(10) Pub. No.: US 2025/0029769 A1
(43) Pub. Date: Jan. 23, 2025

(54) INDUCTOR AND TRANS-INDUCTOR VOLTAGE REGULATOR

(71) Applicants: HUIZHOU POCO NEW INDUCTOR TECHNOLOGY CO., LTD., Huizhou City (CN); SHENZHEN POCO MAGNETIC CO., LTD., Shenzhen City (CN); HUIZHOU POCO INDUSTRY CO., LTD., Huizhou City (CN); HEYUAN POCO MAGNETIC CO., LTD., Heyuan City (CN)

(72) Inventors: TAO LUO, Shenzhen City, Guangdong Province (CN); XIONGZHI GUO, Shenzhen City, Guangdong Province (CN); YUNFAN ZHANG, Shenzhen City, Guangdong Province (CN)

(21) Appl. No.: 18/772,248

(22) Filed: Jul. 14, 2024

(30) Foreign Application Priority Data
Jul. 17, 2023 (CN) 202310877663.0

(51) Int. Cl. H01F 27/28; H01F 27/24; H01F 27/32; H05K 1/18

(52) U.S. Cl. CPC H01F 27/28; H01F 27/24; H01F 27/323; H05K 1/181; H05K 2201/1003

(57) ABSTRACT

An inductor provided in the present invention, includes a magnetic core and one or more conductive coil assembly embedded in the magnetic core; each conductive coil assembly comprises an inner conductive coil and an outer conductive coil surrounding the inner conductive coil. The inner conductive coil is enclosed in the outer conductive coils to form an inner and outer nested structure; the inner conductive coil and the outer conductive coil are arranged in parallel and spaced apart at a distance therebetween closed enough to obtain a coupling coefficient of more than 0.9.

### CROSS REFERENCE TO RELATED APPLICATIONS

The present invention is 35 U.S.C. § 119 benefit of earlier filing dates; rights of priority of Chinese Applications No. 202310877663.0 filed on Jul. 17, 2023, the disclosure of which is incorporated by reference herein.

### BACKGROUND OF THE INVENTION

### Field of the Invention

The present invention relates to the field of electronic components, and more particularly, to an inductor.

### Description of Related Art

At present, most traditional coupled inductors are assembled structures, and the materials of the magnetic core generally are ferrite. The magnetic core, conductive coils and coupling are assembled together to obtain the coupled inductor. The assembled inductor is not suitable for trans-inductor voltage regulator (TLVR), and there is a problem of low inductive coupling. The magnetic core and conductive coils cannot be in full contact in the assembled inductor, the power density is low, and the heat dissipation is insufficient.

### SUMMARY OF THE INVENTION

An object of the present invention is to is to provide an inductor to solve the problems of low inductive coupling of existing inductors.

An inductor provided by the present invention, comprises a magnetic core, and one or more conductive coil assembly embedded in the magnetic core. Each conductive coil assembly comprises an inner conductive coil and an outer conductive coil surrounding the inner conductive coil; wherein the inner conductive coil is enclosed in the outer conductive coils to form an inner and outer nested structure; the inner conductive coil and the outer conductive coil are spaced apart at a distance closed enough to obtain a coupling coefficient of more than 0.9; and leads of the inner and outer conductive coils are exposed on a surface of the magnetic core for electronical connection with a circuit board.

In some embodiments, the inner and outer conductive coils are single turn and are open on the same side where the leads extend; and the inner conductive coil is completely surrounded by the outer conductive coil.

In some embodiments, the distance between the inner conductive coil and the outer conductive coil is 0.1-0.5 cm.

In some embodiments, along a centerline direction of each conductive coil assembly, the inner conductive coil and the outer conductive coil are in parallel, nested and aligned to each other; the inner conductive coil and the outer conductive coil have adapted size and shape.

In some embodiments, the conductive coil assemblies are parallel and spaced apart and their centerlines are parallel; or the conductive coil assemblies have a common centerline and are parallel and spaced apart along the common centerline.

In some embodiments, the inner and outer conductive coils have a “U” or “C” shape each with two leads at both sides extending to the same open side thereof, the same open side is on a first side surface of the magnetic core; the two leads of each the inner and outer conductive coil are exposed on the first side surface and/or two opposite second side surfaces of the magnetic core for electrical connections with the circuit board, and the first side surface is adjacent to and in connection between the two opposite second side surfaces.

In some embodiments, two lead terminals of each the inner and outer conductive are bent along the same open side or along said first side surface of the magnetic core, or straightly extend to the same open side or to the first side surface of the magnetic core.

In some embodiments, two lead terminals of the outer conductive are bent outward along or straightly extend to the same open side, and are embedded in or protrude outward from the first side surface and/or the second side surfaces of the magnetic core; two lead terminals of the inner conductive coil are bent inward along or straightly extend to the same open side, and are embedded in or protrude outward from the first side surface.

In some embodiments, the first side surface of the magnetic core with the lead terminals therein keeps flat or planar; the inner conductive coil and the outer conductive coil are each symmetrical.

In some embodiments, cross-sectional shapes of the inner conductive coil and the outer conductive coil are adapted for each other; the inner conductive coil and the outer conductive coil are equally spaced in parallel; the cross-sectional shapes of the inner and outer conductive coils are polygon, circle, or ellipse; the inner conductive coil and the outer conductive coil are configured as non-closed polygon, circle or ellipse; the inner conductive coil is surrounded in parallel by the outer conductive coil.

In some embodiments, two leads of the outer conductive coil are bent in opposite directions away from each other along a first side surface of the magnetic core, or are parallel straight lines extending toward the first side surface; two leads of the inner conductive coil are bent toward each other along the first side surface of the magnetic core, or are parallel straight lines extending toward the first side surface; terminals of the two leads of each the inner and outer conductive coils are spaced apart on the first side surface, and arranged in a straight line.

In some embodiments, the inner conductive coil and/or the outer conductive are covered with an insulating layer to provide insulation and close spacing between the inner and outer conductive coil.

In some embodiments, the magnetic core and the one or more conductive coil assemblies are integrated into an integrated inductor by means of an integrated molding process using magnetic powder filing around the conductive coil assembly in one mold, whereby the magnetic core and the conductive coils are fully contacted and tightly combined, and magnetic powder is distributed around the conductive coils to provide insulation and close spacing between the inner and outer conductive coil.

In some embodiments, the integrated molding process comprising steps of:
a pressing and molding step; and
an annealing step;
wherein the pressing and molding step is that: pre-installing the one or more conductive coil assemblies in a cavity of the mold, filling the cavity with magnetic powder, applying pressure for molding to obtain a pre-inductor;
the annealing step is that: placing the pre-inductor in a heat treatment furnace for calcinating and annealing so as to release residual stress inside the magnetic core and obtain the integrated inductor.

In some embodiments, the inductor is a single-phase or multi-phase coupling inductor.

The present invention provides a trans-inductor voltage regulator, comprising a circuit board, and the inductor of any of above-described embodiments which is electrically connected to the circuit board.

The advantages of the present invention are:
the inductor of the present invention, includes the conductive coil assembly with an inner coil enclosed in an outer conductive coil; both conductive coils are coupled to each other and embedded in the magnetic core, thereby, a very high coupling coefficient is obtained. The coupling coefficient between the inner coil and outer coil of the same conductive coil assembly can reach more than 0.9, thus a fast response of the inductor is obtained, and a power loss is reduced.

In some embodiments, the inductor of the present invention, the magnetic core and the conductive coils are integrated in one-piece, magnetic powder fully fill gaps in the magnetic core and between the conductive coils, which improves the magnetic permeability and magnetic flux density of the inductor, and reduces the loss. The magnetic core and conductive coils are tightly combined, and have good heat conduction and heat dissipation effects, which can keep the inductor at a lower operating temperature. The magnetic core and conductive coils are molded in one piece to give the inductor a high density.

When there are more conductive coil assemblies are set in the magnetic core, each conductive coil assembly includes inner and outer conductive coils coupled to each other at a high coupling coefficient (more than 0.9), while a coupling between the inner conductive coils and the out conductive coils of different conductive coil assemblies less than 0.5 (preferably less than 0.2), thus there is less interference between different conductive coil assemblies with each other. The coupling between different conductive coil assemblies can be adjusted according to a distance or space between the adjacent conductive coil assemblies, or can be adjusted according to a projection overlap in one view of the adjacent conductive coil assemblies.

Further, the one-piece inductor of the present invention has a simple manufacturing process which is easy to implement automatically and has low cost.

Further, the one-piece inductor of the present invention has a shielded magnetic circuit and has a function of resisting electromagnetic interference.

Further, the one-piece inductor of the present invention is adapted for a SMT (Surface Mounted Technology) process to facilitate a mass production of PCB.

### BRIEF DESCRIPTION OF DRAWINGS

FIG. 1 illustrates a perspective view of an inductor in accordance with an embodiment of the present invention;

FIG. 2 illustrates a cross-sectional view of the inductor in accordance with the first embodiment of the present invention;

FIG. 3 illustrates a perspective view of the inductor in accordance with a second embodiment of the present invention;

FIG. 4 illustrates a perspective view of an internal structure of the inductor in accordance with the second embodiment of the present invention;

FIG. 5 illustrates a cross-sectional view of the inductor in accordance with the second embodiment of the present invention;

FIG. 6 illustrates a perspective view of the inductor in accordance with a third embodiment of the present invention; and

FIG. 7 illustrates a cross-sectional view of the inductor in accordance with the third embodiment of the present invention.

### DETAILED DESCRIPTION OF THE INVENTION

An inductor is described herein. Exemplary embodiments of the present invention will be described in more detail below with reference to the accompanying drawings. Although exemplary embodiments of the present invention are shown in the drawings, it should be understood that the present invention may be implemented in various forms and should not be limited to the embodiments described below. Rather, these embodiments are provided to enable those skilled in the art to completely understand the present invention.

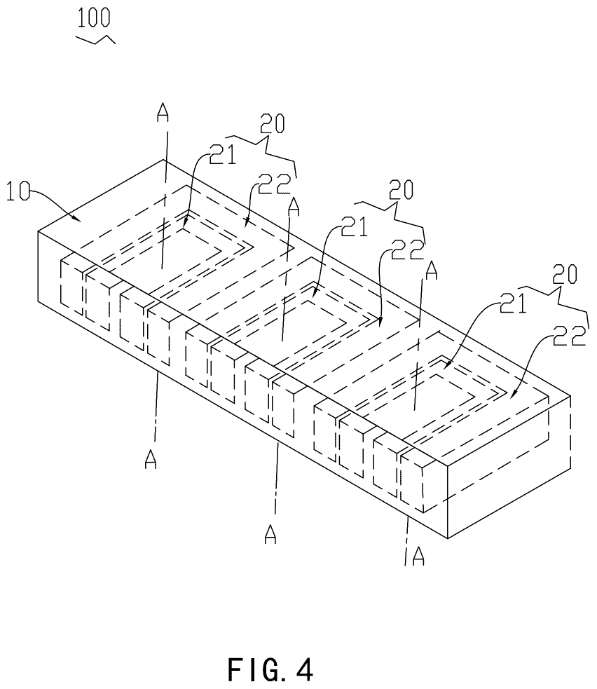

Certain terminology is used in the following description for convenience only and is not limiting. The words “a”, “an” and “one”, as used in the claims and in the corresponding portions of the specification, are defined as including one or more of the referenced items unless specifically stated otherwise. This terminology includes the words above specifically mentioned, derivatives thereof, and words of similar import. The phrase “at least one” followed by a list of two or more items, such as “A, B, or C,” means any individual one of A, B or C as well as any combination thereof. It may be noted that some Figures (such as FIG. 4) are shown with partial transparency for the purpose of explanation, illustration and demonstration purposes only, and is not intended to indicate that an element itself would be transparent in its final manufactured form.

Although the terms first, second, etc. may be used herein to describe various elements, components, regions, layers and/or sections; these elements, components, regions, layers and/or sections shall not be referred to as limited by these terms. These terms are only used to distinguish one element, component, region, layer or section from another element, component, region, layer or section. Terms such as “first,” “second,” and other numerical terms when used herein do not imply a sequence or order unless clearly indicated by the context. Thus, an element, component, region, layer or section discussed below could be termed a second element, component, region, layer or section without departing from the teachings of the example embodiments.

For ease of description, orientational terms may be used herein to describe the relationship of one element or feature to another element or feature as shown in the figures, such as “internal”, “external”, “inside”, “outside”, “below”, “beneath”, “under”, “above”, “on”, “top”, “bottom”, “front”, “rear”, “left”, “right”, etc. Such orientational terms are intended to encompass different orientations of the device in use or operation in addition to the orientation depicted in the figures and description. For example, if the device in the figures is turned over, elements described as “below” or “beneath” or “under” other elements or features would then be oriented “above” or “on” the other elements or features. Thus, the example term “below” may include an orientation of above and below. The device may be otherwise oriented (rotated 90 degrees or at other orientations) and the orientation herein should be interpreted accordingly.

The experimental methods described in the following examples, if no special limitations are given, are conventional methods; the reagents and materials, if no special limitations are given, can be obtained from commercial sources.

Numerical values or value ranges disclosed herein are not limited to the precise values or range, but should be understood to include values approaching these ranges or values. For numerical ranges, the endpoints and any point values within the range, individual or combined with each other to obtain one or more new value ranges, shall be deemed to be specifically disclosed herein.

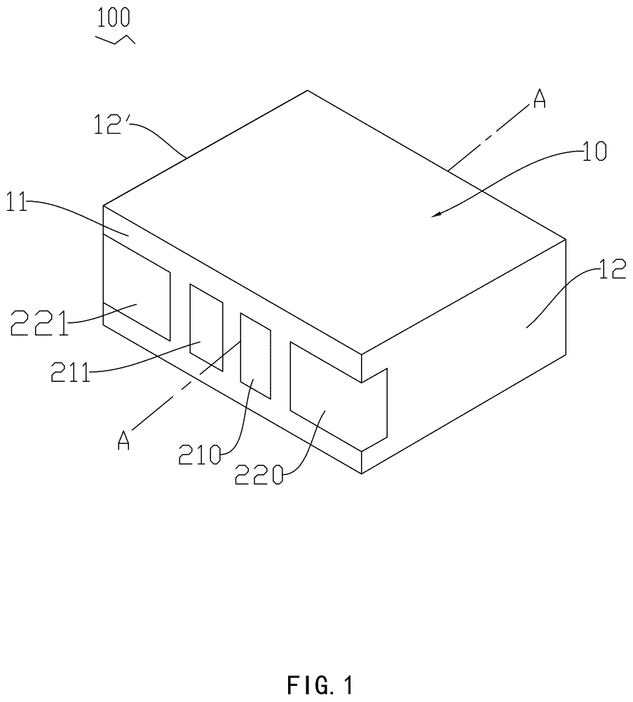

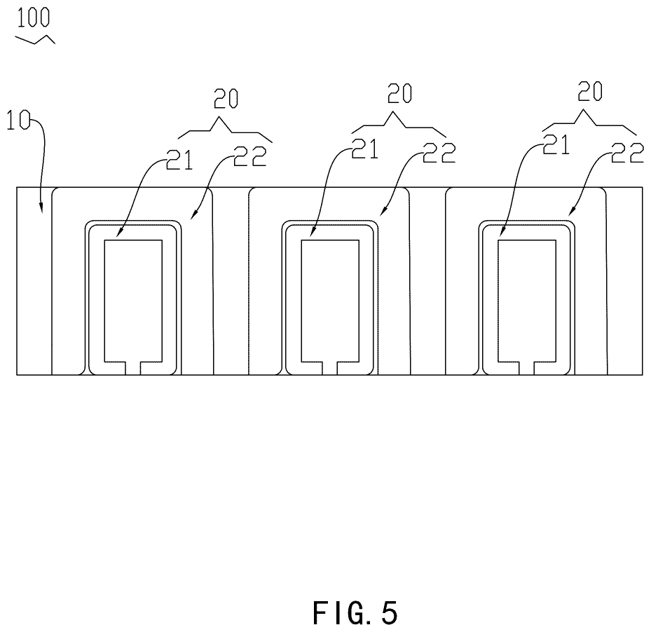

Referring to FIGS. 1-7, an inductor 100 of the present invention includes a magnetic core 10 and one or more conductive coil assembly 20 embedded inside the magnetic core 10. The magnetic core 10 and the conductive coil assembly 20 can be formed into an integrated structure by means of a molding process by filling magnetic powder around the conductive coil assembly 20 preinstalled in a mold. The molding process comprises the following steps:
a pressing and molding step, specifically: pre-installing conductive coil assembly(s) 20 in a mold, filling the mold cavity with magnetic powder, applying pressure for molding, where the molding pressure can be 12˜24 T/cm², then obtaining a pre-inductor of which conductive coils are embedded in a magnetic core and the leads of the conductive coils are exposed on the surface(s) of the magnetic core; and
an annealing step: placing the pre-inductor in a heat treatment furnace for calcinating and annealing so as to release residual stress inside the magnetic core, and obtaining the inductor with a high dynamic response, where annealing temperature can be 400˜850° C.

Magnetic powder can be insulating (soft) magnetic powder (particles), and the insulating magnetic powder can be one or more of Fe-based powder, Fe—Si powder, Fe—Si—Al alloy powder, Fe—Ni alloy powder, etc., or amorphous powder thereof. During the molding process, soft magnetic powder is filled around conductive coils in the mold, soft magnetic powder material is evenly distributed between the conductive coils and make the conductive coils electrically insulated from each other. The magnetic core and conductive coils fully contact to obtain a rapid heat transfer. The molding process at a high-pressure (12˜24 T/cm²) significantly reduces air gaps inside the inductor (or inside magnetic core), through which an inductor can be obtained with full space utilization and at a high-power density. A single-phase or multi-phase inductor with a high dynamic response can be manufactured by means of molding soft magnetic powder filled around multiple conductive coils in one mold, which can save a volume of the inductor. The inductor of the present invention has a smaller profile and high-power density.

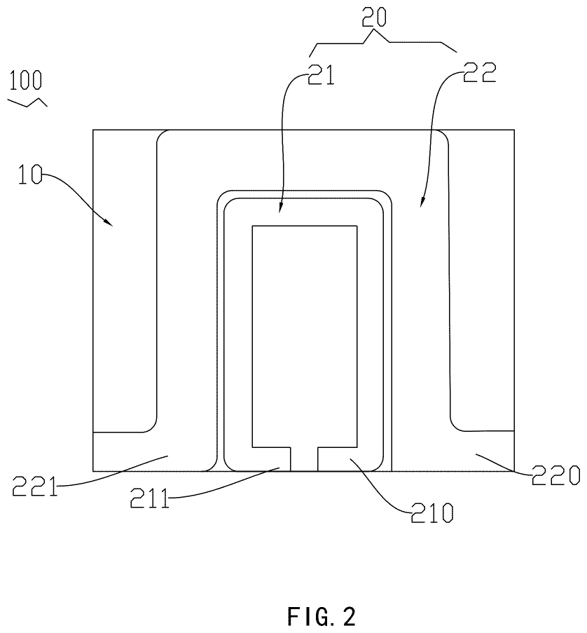

Referring to FIGS. 1-2, the inductor 100 in accordance with a first embodiment includes a square (not limited to square) magnetic core 10 and a conductive coil assembly 20 embedded in the magnetic core 10. The conductive coil assembly 20 includes an inner conductive coil 21 and an outer conductive coil 22. The inner conductive coil 21 is nested within the outer conductive coil 22 and the outer conductive coil 22 surrounds the inner conductive coil 21, thereby forming an inner and outer annular nested structure. In one embodiment, the inner conductive coil 21 and the outer conductive coil 22 are each a single turn coil, and are open on the same side. In a direction of the vertical centerline (central axis) AA of each conductive coil assembly 20, the inner conductive coil 21 and the outer conductive coil 22 are arranged parallel to each other and at the same height. In some embodiments, the inner conductive coil 21 and/or the outer conductive coil 22 are covered with an insulating layer which provides a spacing and electrical insulation between the inner conductive coil 21 and the outer conductive coil 22. In other embodiments, during the molding process for manufacturing the integrated inductor, insulating magnetic powder is filled between the inner conductive coil and the outer conductive coil to form an insulating layer therebetween which provides electrical insulation and a sufficiently close distance therebetween whereby a high coupling coefficient of the inductor 100 can be obtained. As an exemplary embodiment, the molding process for manufacturing the integrated inductor includes: placing the conductive coil assembly 20 in a mold, filing the mold's cavity with insulating magnetic powder, and molding under a high pressure to obtain the one-piece (integrated) inductor; wherein the insulating magnetic powder are pressed to form the magnetic core, the conductive coil assembly 20 is embedded in the magnetic core, the insulating magnetic powder material is evenly distributed between the inner conductive coil and the outer conductive coil and forms the insulating layer which provides electrical insulation and a sufficiently close spacing between the inner and outer conductive coils to obtain a high coupling coefficient of the inductor 100; and there is almost no air gap inside the inductor 100 (or inside the magnetic core). The inner and outer conductive coils 21 and 22 are coupled to each other, and there must be a distance between the inner conductive coil 21 and the outer conductive coil 22. For example, in the same conductive coil assembly 20, the distance between the inner conductive coil 21 and the outer conductive coil 22 is 0.1-0.5 cm. The distance between the inner and outer conductive coils 21 and 22 is close enough to obtain a high coupling coefficient, such as a coupling coefficient greater than 0.9. Preferably, the inner and outer conductive coils 21 and 22 are each a “U” or “C” shape with an open/a gap at the same side, the two opposite lead terminals of each conductive coil are bent inward or outward forming the open or gap. The lead terminals are exposed on the surface of the magnetic core 10 for electrically connection with the circuit board.

In an exemplary embodiment, the outer conductive coil 22 with its leads 220 and 221 form a symmetrical “U” or “C” shape. The inner conductive coil 21 with its leads 210 and 211 form a symmetrical “U” or “C” shape. The inner conductive coil 21 and the outer conductive coil 22 have matched shape and size, are evenly spaced at a preset distance therebetween, and form parallel nested shape. An overall shape of the outer conductive coil 22 is generally square (not limited to a square), and its two leads 220 and 221 are bent outward at 90 degrees along an unclosed side of the square. The leads 220, 221 extend to a first side surface 11 of the magnetic core 10, the unclosed side of the square is in the first side surface 11. Terminals of the leads 220 and 221 are exposed on the first side surface 11 and its adjacent second side surfaces 12/12′ of the magnetic core 10 and keep the side surfaces 11 and 12/12′ flat or planar. A cross-sectional shape of the outer conductive coil 22 is square (not limited to square). An overall shape of the inner conductive coil 21 is generally square (not limited to a square), and its two leads 210 and 211 are bent at 90 degrees toward each other along an unclosed side of the square. The leads 210 and 211 extend to the first side surface 11 of the magnetic core 10, and the unclosed side of the square is in the first side surface 11. Terminals of the leads 210 and 211 are exposed on the first side surface 11 of the magnetic core 10 and keep the first side surface 11 flat or planar. The ends of the two leads 210 and 211 are opposite and spaced apart. A cross-sectional shape of the inner conductive coil 21 is square (not limited to a square).

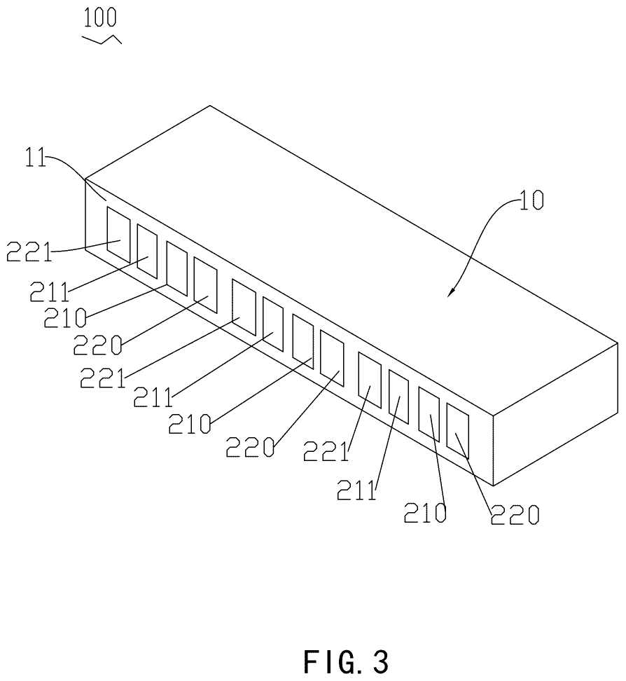

Referring to FIGS. 3-5, wherein, in FIG. 4, the magnetic core 10 is assumed to be transparent to illustrate the conductive coil assembly 20 therein, the inductor 100 of the second embodiment includes a square (not limited to a square) magnetic core 10. Multiple conductive coil assemblies 20 are embedded in the magnetic core 10. The multiple conductive coil assemblies realize multi-phase coupling integration of the inductor. The multiple conductive coil assemblies 20 are embedded in the magnetic core 10 in parallel and at intervals. As an example, three conductive coil assemblies 20 are embedded in the magnetic core 10 in parallel and spaced apart. Centerlines (central axes) AA of the three conductive coil assemblies are parallel and spaced apart from each other. Each conductive coil assembly 20 includes a pair of inner conductive coils 21 and outer conductive coils 22 that are nested inside and outside to form an inner and outer surrounding structure. In the direction of the centerline AA of each conductive coil assembly 20, the inner conductive coil 21 and the outer conductive coil 22 of each conductive coil assembly 20 are arranged at the same high and in parallel. In this embodiment, the inner conductive coil 21 and the outer conductive coil 22 are single-turn coils open on the same side as the leads 210/211 and 220/221 extend to. The outer conductive coil 22 surrounds the inner conductive coil 21 of the same assembly 20. In one exemplar embodiment, the conductive coils 21, 22 are spaced apart and insulated by an insulating layer covered on the inner conductive coil 21 and/or the outer conductive coil 22. In another exemplar embodiment, the conductive coils 21, 22 are spaced apart and insulated by the insulating magnetic core 10, wherein the conductive coil assembly 20 and insulating magnetic powder are placed in one mold and co-molded into a one-piece inductor, the insulating magnetic powder material is evenly distributed between the coils 21 and 22, so that the inner conductive coil 21 and the outer conductive coil 22 are properly spaced and insulated from each other, and there is no air gap inside the inductor. The inner and outer conductive coils 21 and 22 are coupled to each other, and there must be a distance between the inner conductive coil 21 and the outer conductive coil 22. For example, the distance between the inner conductive coil 21 and the outer conductive coil 22 is 0.1-0.5 cm. The distance between the inner and outer conductive coils 21 and 22 is close enough to achieve a high coupling coefficient, and the distance ensures a coupling coefficient greater than 0.9. The inner and outer conductive coils 21 and 22 are in a “U” or “C” shape and are nested in each other. The “U” or “C” shaped conductive coils 21 and 22 are open on the same side as leads 210/211 and 220/221 of the conductive coils 21/22 extend to. Leads 210/211 and 220/221 are exposed on the side surface of the magnetic core 10 for electrically connecting to a circuit board.

In the exemplar embodiment, the outer conductive coil 22 with its leads 220 and 221 form a symmetrical “U” or “C” shape. The inner conductive coil 21 with its leads 210 and 211 form a symmetrical “U” or “C” shape. The inner conductive coil 21 and the outer conductive coil 22 have matched shape and size and are evenly spaced at a preset distance therebetween. The inner conductive coil 21 and the outer conductive coil 22 are matched to form inner and outer “U” and/or “C” shapes that are parallel to each other and nested in each other. The single-turn outer conductive coil 22 is generally square (not limited to a square) with one side open, and its two leads 220 and 221 extend to a first side surface 11 of the magnetic core 10 in parallel and spaced apart. Terminals of the leads 220 and 221 are exposed on the first side surface 11 of the magnetic core 10 and keep the side surface 11 flat or planar. A cross-sectional shape of the outer conductive coil 22 is square (not limited to square). The single-turn inner conductive coil 21 is generally square (not limited to a square) with the same side open as the outer conductive coil 22, and its two leads 210 and 211 are bent at 90 degrees toward each other along the same open side of the square. The leads 210 and 211 extend to the first side surface 11 of the magnetic core 10. Terminals of the leads 210 and 211 are exposed on the first side surface 11 of the magnetic core 10 and keep the first side surface 11 flat or planar. The ends of the two leads 210 and 211 are opposite and spaced apart. A cross-sectional shape of the inner conductive coil 21 is square (not limited to a square).

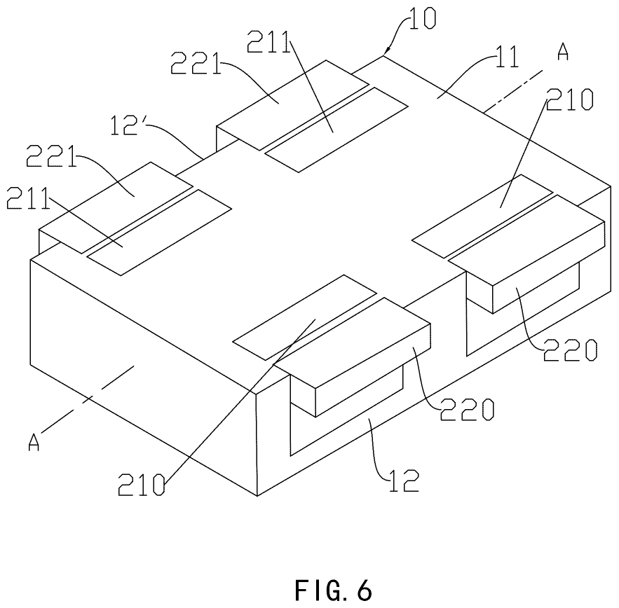

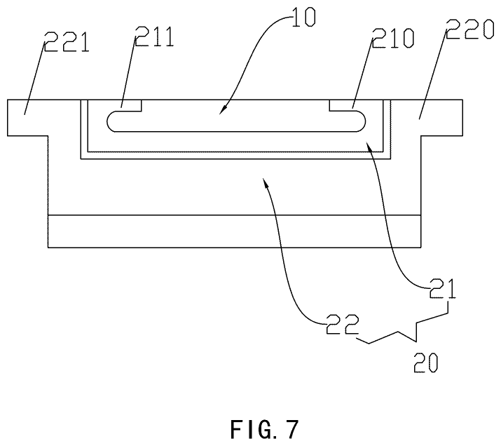

Referring to FIGS. 6-7, the inductor 100 in accordance with the third embodiment includes a square (not limited to a square) magnetic core 10. Multiple conductive coil assemblies 20 are embedded in the magnetic core 10. The multiple conductive coil assemblies form multi-phase coupling integration. The conductive coil assemblies 20 are embedded in the magnetic core 10 in parallel and at intervals. As an example, two conductive coil assemblies 20 are embedded in the magnetic core 10 in parallel and spaced apart along a common centerline AA of the assemblies 20, and the two conductive coil assemblies 20 has a common centerline (central axis) AA. Each conductive coil assembly 20 includes a pair of inner conductive coils 21 and outer conductive coils 22 that are nested inside and outside to form an inner and outer surrounding structure. In this embodiment, the inner conductive coil 21 and the outer conductive coil 22 are single-turn coils open on the same side which is in the first side surface 11 of the magnetic core 10. The outer conductive coil 22 surrounds the inner conductive coil 21. For each conductive coil assembly 20, the conductive coils 21, 22 are spaced apart and insulated by an insulating layer covered on the inner conductive coil 21 and/or the outer conductive coil 22. In another exemplar embodiment, the conductive coils 21, 22 are spaced apart and insulated by the insulating magnetic core 10, wherein the conductive coil assembly 20 and insulating magnetic powder are placed in one mold and co-molded into a one-piece inductor, the insulating magnetic powder material is evenly distributed between the coils 21 and 22, such that the inner conductive coil 21 and the outer conductive coil 22 are properly spaced and insulated from each other, and there is no air gap inside the inductor. The inner and outer conductive coils 21 and 22 are coupled to each other, and there must be a distance (spacing) between the inner conductive coil 21 and the outer conductive coil 22. For example, the distance (spacing) between the inner conductive coil 21 and the outer conductive coil 22 is 0.1-0.5 cm. The distance between the inner and outer conductive coils 21 and 22 is close enough to achieve a high coupling coefficient, and the distance ensures a coupling coefficient greater than 0.9. The inner and outer conductive coils 21 and 22 are in a “U” or “C” shape and are nested in each other. The “U” or “C” shaped conductive coils 21 and 22 are open on the same side as the leads 210/211 and 220/221 of the conductive coils 21/22 extend to, and the leads are exposed on the side surface of the magnetic core 10 for electrically connecting to the circuit board.

In this embodiment, the outer conductive coil 22 is in a “U” shape with its leads 220 and 221 on both side; the inner conductive coil 21 is in a “U” or “C” shape with its leads 210 and 211 on both sides. The “U” or “C” shaped inner and outer conductive coils 21 and 22 are open on the same side which is in the first side surface 11 of the magnetic core 10. The inner conductive coil 21 and the outer conductive coil 22 have matched shape and size, are evenly spaced at a preset distance therebetween, have matched heights (for example, the same heights) in the centerline direction of the conductive coil assembly, such that forming an inner and outer surrounding (nested) “U” and/or “C” shape. The two leads 220 and 221 of the outer conductive coil 22 extend to the first side surface 11 of the magnetic core 10, are exposed on the first side surface 11 and its two adjacent second side surfaces 12/12′, and are bent outwards at 90 degrees (not limited to 90 degrees) from the first side surface 11 to its either adjacent side surfaces 12/12′. The two leads 220 and 221 extend from the side surface 11 to the adjacent side surfaces 12/12′, and keep the side surface 11 flat or planar, that is, the lead 220 extends through a groove in the side surfaces 11 and 12 and the lead 221 extends through a groove in the side surfaces 11 and 12′ (the side surfaces 12 and 12′ are opposite). The two leads 210 and 211 of the inner conductive coil 21 extend to and exposed on the first side surface 11 of the magnetic core 10, are exposed on the first side surface 11 for electrical connection with the circuit board. Further, the leads 210 and 211 are bent towards each other at 90 degrees (not limited to 90 degrees) and keep the side surface of the magnetic core 10 flat or planar, that is, the terminals of the leads 210 and 211 are embedded in the grooves in the first side surface 11 of the magnetic core 10 and keep the side surface flat. The terminals of the leads 210 and 211 are spaced apart.

The one-piece inductor 100 of the present invention includes a magnetic core 10 and one or more conductive coil assemblies 20 inside the magnetic core 10. Each conductive coil assembly includes two inner and outer conductive coils 21/22 which are nested in each other to form a coupled inner and outer surrounding structure. The inner and outer conductive coils 21/22 may be arranged parallel and at the same height along a centerline direction of each assembly 20. The two conductive coils 21 and 22, arranged with one inner and another outer, are spaced apart and insulated from each other by an insulating layer covered on the inner conductive coil 21 and/or the outer conductive coil 22, or spaced apart and insulated from each other by filling insulating magnetic powder around the coils 21 and 22 during molding the magnetic core 10. A coupling coefficient greater than 0.9 can be obtained by the close spacing between the conductive coils 21 and 22. The magnetic core 10 can integrated one or more conductive coil assemblies 20 to form the inductor 100. Preferably, the inductor 100 is manufactured by means of an integrated molding process (or one-piece molding process). During the integrated molding process, pre-install one or more conductive coil assemblies 20 in a mold, fill the mold cavity with insulating magnetic powder (such as Fe-based powder, Fe—Si alloy powder, Fe—Si—Al alloy magnetic powder, Fe—Ni alloy powder, etc.), and mold under a high pressure molding, such that obtain the integrated inductor with the one or more conductive coil assemblies 20 embedded in the magnetic core 10. The magnet core and conductive coils are in full contact to achieve rapid heat transfer. The high-pressure molding leaves no air gaps inside the inductor, which can obtain full space utilization and high-power density. There must be a gap/distance between the inner conductive coil 21 and the outer conductive coil 22. The integrated inductor 100 of the present invention has good heat dissipation and simpler production; and is suitable for SMT process; the distance between the inner and outer conductive coils of the same assembly 20 is close enough to obtain a very high coupling coefficient, and a coupling coefficient of up to 0.9 or more can be obtained. The inductor 100 can have single-phase or multiple-phase conductive coils integrated in the magnetic core 10, thus obtain a small size/profile and high-power density. Insulating magnetic powder material is evenly distributed around each conductive coil to form a suitable spacing and insulation between the inner and outer conductive coils.

The inductor 100 of the present invention is used as an inductor for a trans-inductor voltage regulator (TLVR). The TLVR comprise a circuit board, and the inductor 100 is electrically connected with a circuit in the circuit board.

The inductor of the present invention, when used in a power supply, can integrate multiple conductive coils in a single magnetic device, thereby can reduce the number of magnetic components, the volume/dimensions and weight of the power supply, thus improve the power density of the power supply, minimize connecting lines between magnetic components, reduce losses, and improve the output filtering effect.

In other embodiments, the inner conductive coil 21 and the outer conductive coil 22 can also be multi-turn coils. The number of turns of the inner conductive coil 21 and the outer conductive coil 22 is determined according to the specific parameter requirements of the inductor, and is not limited.

The technical features of the above embodiments can be combined arbitrarily. In order to make the description simple, all possible combinations of the technical features in the above embodiments are not described. However, as long as there is no contradiction in the combination of these technical features It is considered to be the range described in this specification.

The above examples only represent several embodiments of the present invention, and the descriptions thereof are specific and detailed, but should not be construed as a limitation on the scope of the invention patent. It should be pointed out that for those of ordinary skill in the art, without departing from the concept of the present invention, several modifications and improvements can also be made, which all belong to the protection scope of the present invention. Therefore, the protection scope of the patent of the present invention should be subject to the appended claims.

What is claimed is:

1. An inductor, comprising:
a magnetic core; and
one or more conductive coil assembly embedded in the magnetic core, each conductive coil assembly comprising:
an inner conductive coil; and
an outer conductive coil surrounding the inner conductive coil;
wherein the inner conductive coil is enclosed in the outer conductive coils to form an inner and outer nested structure; the inner conductive coil and the outer conductive coil are spaced apart at a distance closed enough to obtain a coupling coefficient of more than 0.9; and leads of the inner and outer conductive coils are exposed on a surface of the magnetic core for electronical connection with a circuit board.

2. The inductor as claimed in claim 1, wherein the inner and outer conductive coils are single turn and are open on the same side where the leads extend; and the inner conductive coil is completely surrounded by the outer conductive coil.

3. The inductor as claimed in claim 1, wherein the distance between the inner conductive coil and the outer conductive coil is 0.1-0.5 cm.

4. The inductor as claimed in claim 1, wherein along a centerline direction of each conductive coil assembly, the inner conductive coil and the outer conductive coil are in parallel, nested and aligned to each other; the inner conductive coil and the outer conductive coil have adapted size and shape.

5. The inductor as claimed in claim 1, wherein the conductive coil assemblies are parallel and spaced apart and their centerlines are parallel; or
the conductive coil assemblies have a common centerline and are parallel and spaced apart along the common centerline.

6. The inductor as claimed in claim 2, wherein the inner and outer conductive coils have a “U” or “C” shape each with two leads at both sides extending to the same open side thereof, the same open side is on a first side surface of the magnetic core; the two leads of each the inner and outer conductive coil are exposed on the first side surface and/or two opposite second side surfaces of the magnetic core for electrical connections with the circuit board, and the first side surface is adjacent to and in connection between the two opposite second side surfaces.

7. The inductor as claimed in claim 6, wherein two lead terminals of each the inner and outer conductive are bent along the same open side or along said first side surface of the magnetic core, or straightly extend to the same open side or to the first side surface of the magnetic core.

8. The inductor as claimed in claim 7, wherein two lead terminals of the outer conductive are bent outward along or straightly extend to the same open side, and are embedded in or protrude outward from the first side surface and/or the second side surfaces of the magnetic core; two lead terminals of the inner conductive coil are bent inward along or straightly extend to the same open side, and are embedded in or protrude outward from the first side surface.

9. The inductor as claimed in claim 8, wherein the first side surface of the magnetic core with the lead terminals therein keeps flat or planar; the inner conductive coil and the outer conductive coil are each symmetrical.

10. The inductor as claimed in claim 1, wherein cross-sectional shapes of the inner conductive coil and the outer conductive coil are adapted for each other; the inner conductive coil and the outer conductive coil are equally spaced in parallel; the cross-sectional shapes of the inner and outer conductive coils are polygon, circle, or ellipse; the inner conductive coil and the outer conductive coil are configured as non-closed polygon, circle or ellipse; the inner conductive coil is surrounded in parallel by the outer conductive coil.

11. The inductor as claimed in claim 1, wherein two leads of the outer conductive coil are bent in opposite directions away from each other along a first side surface of the magnetic core, or are parallel straight lines extending toward the first side surface; two leads of the inner conductive coil are bent toward each other along the first side surface of the magnetic core, or are parallel straight lines extending toward the first side surface; terminals of the two leads of each the inner and outer conductive coils are spaced apart on the first side surface, and arranged in a straight line.

12. The inductor as claimed in claim 1, wherein the inner conductive coil and/or the outer conductive are covered with an insulating layer to provide insulation and close spacing between the inner and outer conductive coil.

13. The inductor as claimed in claim 1, wherein the magnetic core and the one or more conductive coil assemblies are integrated into an integrated inductor by means of an integrated molding process using magnetic powder filing around the conductive coil assembly in one mold, whereby the magnetic core and the conductive coils are fully contacted and tightly combined, and magnetic powder is distributed around the conductive coils to provide insulation and close spacing between the inner and outer conductive coil.

14. The inductor as claimed in claim 13, wherein the integrated molding process comprising steps of:
a pressing and molding step; and
an annealing step;
wherein the pressing and molding step is that: pre-installing the one or more conductive coil assemblies in a cavity of the mold, filling the cavity with magnetic powder, applying pressure for molding to obtain a pre-inductor;
the annealing step is that: placing the pre-inductor in a heat treatment furnace for calcinating and annealing so as to release residual stress inside the magnetic core and obtain the integrated inductor.

15. The inductor as claimed in claim 14, wherein at the pressing and molding step, the pressure for molding is 12˜24 T/cm²; and at the annealing step, a temperature in the heat treatment furnace is 400˜850° C.

16. The inductor as claimed in claim 1, wherein the inductor is a single-phase or multi-phase coupling inductor.

17. A trans-inductor voltage regulator, comprising:
a circuit board; and
an inductor electrically connected to the circuit board, the inductor comprising:
a magnetic core; and
one or more conductive coil assembly embedded in the magnetic core, each conductive coil assembly comprising:
an inner conductive coil; and
an outer conductive coil surrounding the inner conductive coil;
wherein the inner conductive coil is enclosed in the outer conductive coils to form an inner and outer nested structure; the inner conductive coil and the outer conductive coil are arranged in parallel and spaced apart at a distance therebetween closed enough to obtain a coupling coefficient of more than 0.9; and leads of the inner and outer conductive coils are exposed on a surface of the magnetic core for electronical connection with the circuit board.
